(19) United States
(12) Patent Application Publication
(10) Pub. No.: US 2007/0227883 A1
(43) Pub. Date: Oct. 4, 2007

(54) SYSTEMS AND METHODS FOR A HELIUM ION PUMP

(76) Inventors: Billy W. Ward, Merrimac, MA (US); John A. Notte IV, Gloucester, MA (US)

Correspondence Address: FISH & RICHARDSON PC, P.O. BOX 1022, MINNEAPOLIS, MN, 55440-1022, US

(21) Appl. No.: 11/688,602

(22) Filed: Mar. 20, 2007

Related U.S. Application Data
(63) Continuation-in-part of application No. 11/385,136, filed on Mar. 20, 2006.
(63) Continuation-in-part of application No. 11/385,215, filed on Mar. 20, 2006.
(63) Continuation-in-part of application No. 11/600,711, filed on Nov. 15, 2006.
(60) Provisional application No. 60/784,389, filed on Mar. 20, 2006.
(60) Provisional application No. 60/784,390, filed on Mar. 20, 2006.
(60) Provisional application No. 60/784,388, filed on Mar. 20, 2006.
(60) Provisional application No. 60/784,331, filed on Mar. 20, 2006.
(60) Provisional application No. 60/784,500, filed on Mar. 20, 2006.
(60) Provisional application No. 60/795,806, filed on Apr. 28, 2006.
(60) Provisional application No. 60/799,203, filed on May 9, 2006.

(51) Int. Cl. C23C 14/00

(52) U.S. Cl. 204/298.16

(57) ABSTRACT

Ion pump systems and methods are disclosed.

### CROSS-REFERENCE TO RELATED APPLICATIONS

This application is a continuation-in-part of, and claims priority under 35 U.S.C. § 120 to: U.S. application Ser. No. 11/385,136, filed Mar. 20, 2006; U.S. application Ser. No. 11/385,215, filed Mar. 20, 2006; and U.S. application Ser. No. 11/600,711, filed Nov. 15, 2006. This application also claims priority under 35 U.S.C. § 119(e)(1) to: U.S. Provisional Application Ser. No. 60/784,389, filed Mar. 20, 2006; U.S. Provisional Application Ser. No. 60/784,390, filed Mar. 20, 2006; U.S. Provisional Application Ser. No. 60/784,388, filed Mar. 20, 2006; U.S. Provisional Application Ser. No. 60/784,331, filed Mar. 20, 2006; U.S. Provisional Application Ser. No. 60/784,500, filed Mar. 20, 2006; U.S. Provisional Application Ser. No. 60/795,806, filed Apr. 28, 2006; and U.S. Provisional Application Ser. No. 60/799,203, filed May 9, 2006. The contents of each of these applications are incorporated herein by reference.

### TECHNICAL FIELD

This disclosure relates to ion pumps, and related systems and methods.

### BACKGROUND

Vacuum systems are often pumped and maintained with ionization pumps that are relatively cheap and reliable. Often, such systems include grounded cylinders with collection plates some small distance away from each end. The collection plates can be biased relative to the cylinders. A large magnetic field can be applied in a direction parallel to the axis of the cylinder. Ion pumps operate, for example, by ionizing gas molecules and accelerating them into titanium or tantalum collection plates. The ionization can be achieved with˜80 eV electrons which are trapped within a grounded cylinder. The gas atoms are then buried some depth below the surface of the collection plates. The impact also can sputter fresh getter materials that can provide a chemical site for bonding other materials.

### SUMMARY

The disclosure relates to ion pumps, and related systems and methods. In a first aspect, the invention features a system that includes a chamber and a member, at least a portion of the member being capable of translating during use of the system, where the chamber and the member are configured so that during use of the system, an electrical potential difference is applied between the chamber and the member so that at least some gas atoms present in the chamber are ionized and at least some of the ions are collected by the member.

In another aspect, the invention features a system that includes a chamber and a member having voids with an average maximum dimension of from 1 nm to 100 nm, where the chamber and the member are configured so that during use of the system an electrical potential difference is applied between the chamber and the member so that at least some gas atoms present in the chamber are ionized and at least some of the ions are collected within the voids of the member.

In a further aspect, the invention features a system that includes a chamber and a member that includes a substrate and a coating on the substrate, where the chamber and the member are configured so that during use of the system, an electrical potential difference is applied between the chamber and the member so that at least some gas atoms present in the chamber are ionized and at least some of the ions are collected within the substrate of the member.

In another aspect, the invention features a system that includes a chamber and a member having a variable thickness wall that defines a trapped volume within the member, where the chamber and the member are configured so that during use of the system, an electrical potential difference is applied between the chamber and the member so that at least some gas atoms present in the chamber are ionized and at least some of the ions are collected within the trapped volume of the member.

In a further aspect, the invention features a system that includes a chamber having at least one open end, a first member disposed adjacent the at least one open end, and a voltage source in electrical communication with the chamber and the first member so that the voltage source applies an electrical potential difference between the chamber and the first member of at least 1,000 V, where the system ionizes at least some gas atoms present in the chamber, and at least some of the ions are implanted in the first member.

In another aspect, the invention features a system that includes a chamber, a member where at least a portion of the member is capable of translating during use of the system, and a voltage source in electrical communication with the chamber and the member, the voltage source configured to apply an electrical potential difference between the chamber and the member.

In a further aspect, the invention features a system that includes a chamber, a member having voids with an average maximum dimension of from 1 nm to 100 nm, and a voltage source in electrical communication with the chamber and the member, the voltage source configured to apply an electrical potential difference between the chamber and the member.

In another aspect, the invention features a system that includes a chamber, a member that includes a substrate and a coating on the substrate, and a voltage source in electrical communication with the chamber and the member, and configured to apply an electrical potential difference between the chamber and the member.

In a further aspect, the invention features a system that includes a chamber, a member having a variable thickness wall that defines a trapped volume within the member, and a voltage source in electrical communication with the chamber and the member, and configured to apply an electrical potential difference between the chamber and the member.

In another aspect, the invention features an ionization system that includes a member having at least a portion capable of translating during use of the ionization system, the member being capable of collecting ions formed by the ionization system.

In a further aspect, the invention features an ionization system that includes a member having voids with an average maximum dimension of from 1 nm to 100 nm, the member being capable of collecting ions formed by the ionization system.

In another aspect, the invention features an ionization system that includes a member that includes a substrate and a coating on the substrate, the member being capable of collecting ions formed by the ionization system.

In a further aspect, the invention features an ionization system that includes a member having a variable thickness wall that defines a trapped volume within the member, the member being capable of collecting ions formed by the ionization system.

In another aspect, the invention features a method that includes forming ions having a potential energy of at least 1,000 V in a system that includes a chamber having at least one open end and a member configured to collect the ions.

Embodiments can include one or more of the following features.

The system can include first and second spools coupled with the member so that, during use, the member moves between the first and second spools in a spool-to-spool fashion.

The member can be in the form of a film. A thickness of the film can be at least 100 nm or more. The thickness of the film can be at most 100 microns or less. A length of the film can be at least 10 m. The length of the film can be at most 5,000 m.

The member can include at least one material selected from the group consisting of a metal, an alloy, and a polymer material. The member can include titanium, tantalum, or both.

The member can include a substrate and a coating on the substrate.

The member can include voids having a maximum dimension of from 10 nm to 100 nm.

The chamber can include a hollow interior volume.

The chamber can include a first open end and a second open end. The member can be a first member, and the system can further include a second member, where the first member is positioned at a distance of less than 10 cm from the first open end and the second member is positioned at a distance of less than 10 cm from the second open end.

The system can include a magnetic field source.

The system can include a source of electromagnetic radiation. The electromagnetic radiation can include at least one type of radiation selected from the group consisting of ultraviolet radiation, visible radiation, and infrared radiation.

The system can include a voltage source in electrical communication with the chamber and the member, and configured to apply an electrical potential difference between the chamber and the member.

The system can include a gas source capable of being placed in fluid communication with the chamber.

The system can include a vacuum chamber in fluid communication with the chamber. The system can include a pump in fluid communication with the vacuum chamber.

The system can include a gas field ion source in the vacuum chamber. The system can further include ion optics configured to direct an ion beam generated by the gas field ion source toward a surface of a sample, where the ion optics include electrodes, an aperture, and an extractor. The system can include a sample manipulator capable of moving the sample.

The system can be a gas field ion microscope. The system can be a helium ion microscope.

The system can be a scanning ion microscope. The system can be a scanning helium ion microscope.

The gas field ion source can include an electrically conductive tip having a terminal shelf with 20 atoms or less.

The voids can have an average maximum dimension of from 10 nm to 80 nm, e.g., from 30 nm to 60 nm.

The substrate can be at least 100 nm thick, e.g., at least 500 nm thick, at least one micron thick. The substrate can be at most 10 mm thick.

The coating can be formed from a plurality of layers.

The substrate can include at least one material selected from the group consisting of a metal, an alloy, and a polymer material. The substrate can include titanium, tantalum, or both.

The coating comprises at least one material selected from the group consisting of a metal, an alloy, and a polymer material.

The coating can include diamond.

At least a portion of the ions can be incident on a portion of the variable thickness wall that has a thickness of 50 nm or more, e.g., a thickness of 500 nm or more. At least a portion of the ions can be incident on a portion of the variable thickness wall that has a thickness of 5 microns or less.

The member can include a base layer and a support layer on the base layer. The support layer can be in the form of a grid. The support layer can include a metal or an alloy. The base layer can include at least one material selected from the group consisting of a metal, an alloy, and a polymer material. The base layer can include titanium, tantalum, or both.

The electrical potential difference between the chamber and the first member can be at least 2,500 V, e.g., at least 5,000 V, at least 7,500 V. The electrical potential difference between the chamber and the first member can be at most 10,000 V.

The system can include a cooling member in thermal communication with the first member. The cooling member can include a heat exchanger. The cooling member can include a Peltier cooler.

During use of the system, the electrical potential difference applied between the chamber and the member can be 1,000 V or more.

Embodiments can include one or more of the following advantages.

Ion pump systems can be used to reduce a background pressure of helium gas in a vacuum chamber to relatively low levels. The ion pump systems can be relatively inexpensive and/or simple to make and/or use. Ion pump systems can be operated while producing relatively little, if any, mechanical vibrations that are introduced into the vacuum chamber.

Ion pump systems can be used, for example, in conjunction with gas source (e.g., a helium gas source), to regulate a backpressure of gas (e.g., helium gas) in a vacuum chamber containing an ion source (e.g., a helium ion source), such as a gas field ion source. Control over the backpressure of the gas can assist in changing the operating parameters of the helium ion source, and in preventing contamination of samples and ion beams due to excess concentrations of helium atoms in the vacuum chamber.

Other features and advantages will be apparent from the description, drawings, and claims.

### DESCRIPTION OF DRAWINGS

FIG. 1 is a perspective view of an embodiment of an ion pump system.

FIG. 2 is a cross-sectional view of an embodiment of an ion pump system.

FIG. 3 is a cross-sectional view of an embodiment of a member configured to collect gas atoms.

FIG. 4 is a schematic view of an embodiment of a multi-channel chamber.

FIG. 5 is a cross-sectional view of an embodiment of a member configured to collect gas atoms, where the member includes a base layer and a coating.

FIG. 6 is a cross-sectional view of an embodiment of a member configured to collect gas atoms, where the member includes a plurality of voids.

FIG. 7A is a cross-sectional view of an embodiment of a member configured to collect gas atoms, where the member is capable of being translated.

FIG. 7B is a view of the member of FIG. 7A on an expanded scale.

FIG. 8 is a cross-sectional view of an embodiment of a member configured to collect gas atoms, where the member includes a variable thickness wall.

FIG. 9 is a schematic diagram of a gas field ion microscope system.

FIG. 10 is a schematic diagram of a helium ion microscope system.

Like reference symbols in the various drawings indicate like elements.

### DETAILED DESCRIPTION

The ion pump systems disclosed herein can be used to pump a variety of different gases. In particular, these ion pump systems can be used to pump helium gas. For example, the ion pump systems disclosed herein can be used to remove excess helium gas from a vacuum chamber. The vacuum chamber can, in some embodiments, include one or more instruments that feature a gas field ionization source that produces a helium ion beam. Instruments that feature a gas field ionization source can include, for example, helium ion microscopes.

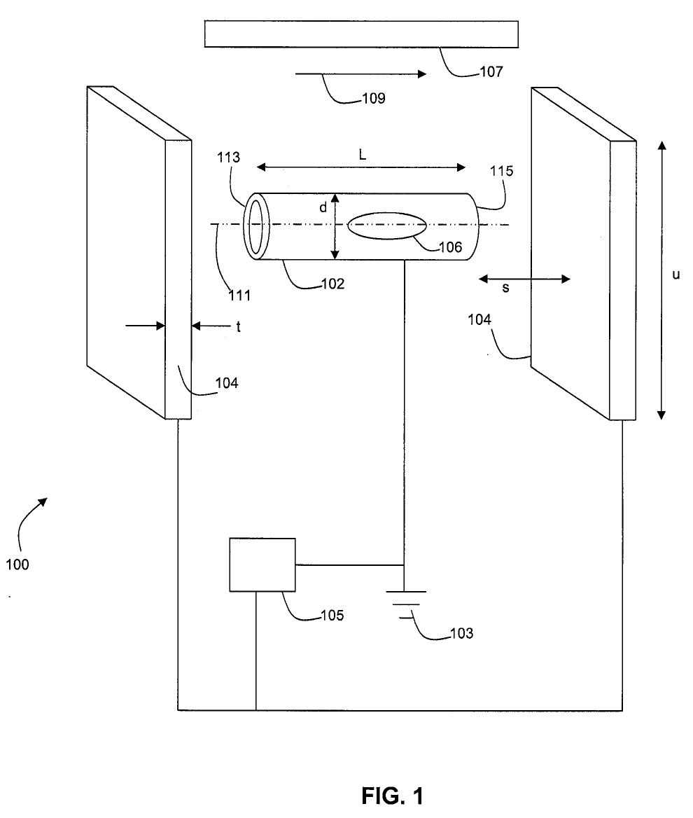

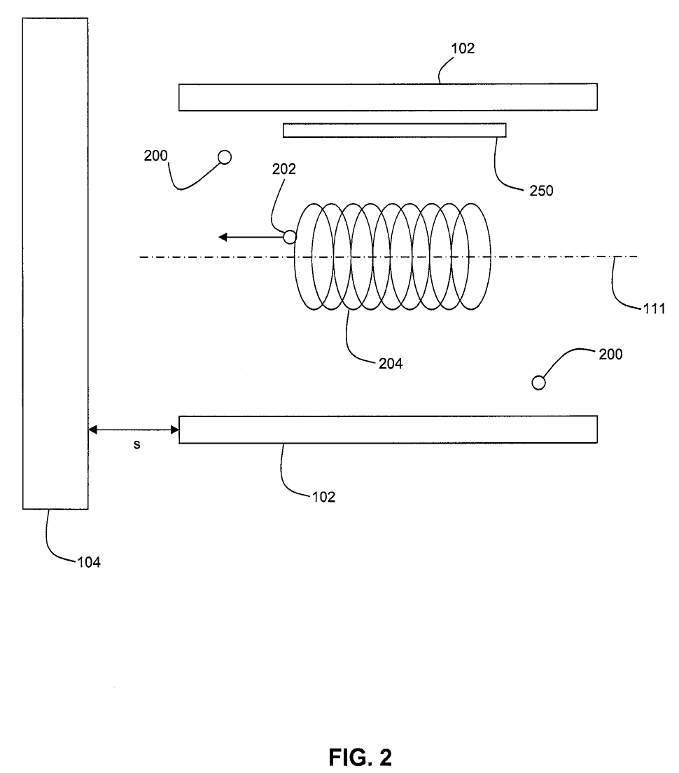

FIGS. 1 and 2 show perspective and cross-sectional views, respectively, of an ion pump system 100 that includes a chamber 102 and members 104. Chamber 102 has a longitudinal axis 111, a maximum dimension d, and a length L. Chamber 102 is spaced from each of members 104 by a distance s measured in a direction parallel to axis 111. Members 104 have a cross-sectional shape that is square with a maximum dimension u, and a thickness t measured in a direction parallel to axis 111.

Chamber 102 is connected to a common electrical ground 103. Members 104 are connected to voltage source 105, which is referenced to common electrical ground 103. Voltage source 105 is configured to apply a relatively large negative electrical potential difference between members 104 and chamber 102 (typically, by maintaining chamber 102 at ground and by applying a relatively large negative potential to members 104).

As a result of the potential difference between members 104 and chamber 102, field ionization occurs at the surfaces of members 104. Field ionization produces a plurality of electrons which experience repulsive forces due to the negative potential of members 104, and which propagate away from members 104 and into chamber 102. The symmetric arrangement of members 104 about chamber 102 produces a net repulsive force on each electron that induces concentration of the electrons within chamber 102 to produce electrons 106. As a result of the forces applied by the electric fields at the surfaces of members 104, electrons 106 travel back and forth within chamber 102 along a trajectory parallel to axis 111, and typically have energies of between about 80 eV and about 100 eV.

System 100 also includes a magnetic field source 107. Magnetic field source 107 is configured to generate a magnetic field 109 in a region of space that includes chamber 102. The field lines of magnetic field 109 are approximately parallel to axis 111 near the center of chamber 102 along axis 111. As a result, magnetic field 109 applies a force to electrons 106 which causes each electron to undergo circular motion in a plane perpendicular to axis 111. Thus, due to the combined forces applied to electrons 106 by the potential difference between members 104 and chamber 102, and magnetic field 109, electrons 106 propagate along helical trajectories 204 (see FIG. 2) within chamber 102.

In some embodiments, the magnitude of magnetic field 109 is 100 Gauss (G) or more (e.g., 200 G or more, 300 G or more, 400 G or more, 500 G or more, 1000 G or more). In certain embodiments, the magnitude of magnetic field 109 is 5,000 G or less (e.g., 4,000 G or less, 3,000 G or less, 2,000 G or less).

As shown in FIG. 2, neutral gas atoms 200 enter chamber 102 and collide with electrons 106 which are circulating within the chamber. Collisions between neutral atoms 200 and electrons 106 cause the neutral gas atoms 200 to be ionized to form ions 202. Ions 202, which are positively charged, experience an attractive force due to the negative potential on members 104 relative to chamber 102, and therefore accelerate towards members 104. Ions 202 are incident on a surface of members 104 and are implanted beneath the incident surface, thereby trapping the ions.

Electrons 106 remain confined within chamber 102 due to: (a) the potential difference between members 104 and chamber 102, which generates an electric field; and (b) magnetic field 109. Electrons 106 circulate back-and-forth in a direction parallel to axis 111 within chamber 102, traveling to regions near the ends of chamber 102 and then returning toward the center of chamber 102.

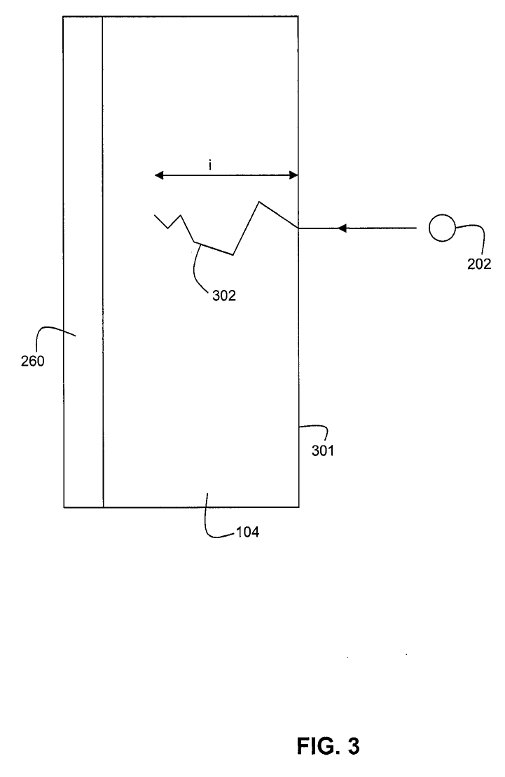

FIG. 3 is a schematic view of an ion 202 incident on a surface 301 of a member 104. After penetrating through surface 301, ion 202 is implanted to a depth i within member 104. The depth i depends upon a number of factors, including the properties of ion 202, the properties of member 104, and the velocity of ion 202 prior to striking the surface of member 104. After penetrating surface 301, ion 202 typically undergoes a series of scattering events with atoms in member 104, and follows a trajectory 302 within member 104. A plurality of ions 202 are incident on surface 301 and are implanted within member 104, although each ion 202 follows a different trajectory 302 within member 104. An average implantation depth i is realized for the plurality of ions 202.

Ion pump system 100 can be used to pump out many different types of gases 200 including noble gases such as helium. Noble gas atoms are typically relatively heavy, and many noble gas atoms are large enough and move slowly enough at room temperature that implantation of the gas atoms beneath surface 301 in member 104 can be fairly long term. However, lighter gases such as helium have high thermal velocity. As a result, there is a greater tendency for implanted helium ions to diffuse out of member 104 and re-enter the surroundings, e.g., a vacuum chamber.

The electrical potential difference between members 104 and chamber 102 is controlled to accelerate the ions 202 and to control a mean implantation depth i of the ions 202 within member 104. For example, if ions 202 include relatively light ions such as helium ions, the potential difference can be increased to implant ions 202 to a relatively larger mean implantation depth i within member 104. As a result, ions 202 implanted to a relatively larger mean implantation depth take a longer time to diffuse out of member 104.

In some embodiments, a potential difference between members 104 and chamber 102 is chosen to be 1,000 V or more (e.g., 1,500 V or more, 2,000 V or more, 2,500 V or more, 3,000 V or more, 5,000 V or more, 7,500 V or more). In certain embodiments, the potential difference between members 104 and chamber 102 is 30,000 V or less (e.g., 25,000 V or less, 20,000 V or less, 15,000 V or less, 12,000 V or less, 10,000 V or less, 8,000 V or less).

In some embodiments, as a result of the potential difference applied between members 104 and chamber 102, ions 202 are accelerated so that they have a mean kinetic energy prior to penetrating surface 301 of 1,000 eV or more (e.g., 1,500 eV or more, 2,000 eV or more, 2,500 eV or more, 3,000 eV or more, 5,000 eV or more, 7,000 eV or more, 7,500 eV or more). In certain embodiments, ions 202 have a mean kinetic energy prior to penetrating surface 301 of 30,000 eV or less (e.g., 25,000 eV or less, 20,000 eV or less, 15,000 eV or less, 12,000 eV or less, 10,000 eV or less, 8,000 eV or less).

In some embodiments, the mean implantation depth i of a plurality of ions 202 within member 104 is 50 nm or more (e.g., 75 nm or more, 100 nm or more, 150 nm or more, 200 nm or more, 300 nm or more, 400 nm or more, 500 nm or more, 600 nm or more, 700 nm or more, 1 micron or more). In certain embodiments, the mean implantation depth of ions 202 is 5 microns or less (e.g., 4 microns or less, 3 microns or less, 2 microns or less).

Members 104 can be formed from a material having a selected lattice spacing. For example, members 104 can be formed from a material having a lattice spacing that is similar to the size of ions 202. As a result, the atomic lattice structure of members 104 contains atomic defect sites that are sized to accept implanted ions 202. In particular, for helium ions 202, members 104 can be formed from a material having lattice spacing on the order of the size of helium ions.

Members 104 can typically be formed from a variety of materials, including metals, alloys, and polymer materials. For example, in some embodiments, members 104 can be formed from a metal such as titanium, tantalum, or both titanium and tantalum. Where members 104 include two or more materials, the two or more materials can be integrally mixed, as in an alloy, or the two or more materials can form a plurality of layers, for example.

Members 104 are shown in FIG. 1 as having a square cross-sectional shape. More generally, however, members 104 can have many different cross-sectional shapes, including circular, elliptical, and rectangular. Cross-sectional shapes of members 104 can be regular or irregular. In some embodiments, the maximum dimension u of members 104 can be 0.5 cm or more (e.g., 1 cm or more, 1.5 cm or more, 2 cm or more, 2.5 cm or more, 3 cm or more, 4 cm or more, 5 cm or more) and/or 30 cm or less (e.g., 20 cm or less, 15 cm or less, 12 cm or less, 10 cm or less, 8 cm or less, 7 cm or less).

The thickness t of members 104 can typically be selected as desired to provide a material for implantation of incident ions 202 with suitable mechanical stability. In some embodiments, t is 50 nm or more (e.g., 100 nm or more, 200 nm or more, 300 nm or more, 400 nm or more, 500 nm or more, 700 nm or more, 1 micron or more, 10 microns or more, 50 microns or more) and/or 10 mm or less (e.g., 5 mm or less, 2 mm or less, 1 mm or less, 800 microns or less, 600 microns or less, 500 microns or less, 400 microns or less, 300 microns or less, 200 microns or less, 100 microns or less).

Chamber 102 is typically formed from a conductive material such as a metal. For example, in some embodiments, chamber 102 is formed from a material such as copper or aluminum. In certain embodiments, chamber 102 can be formed from alloys of two or more materials. For example, chamber 102 can be formed from materials such as steel, e.g., stainless steel.

In some embodiments, the maximum dimension d of chamber 102 is 0.5 cm or more (e.g., 1 cm or more, 1.5 cm or more, 2 cm or more, 2.5 cm or more). In certain embodiments, d is 10 cm or less (e.g., 9 cm or less, 8 cm or less, 7 cm or less, 6 cm or less, 5 cm or less).

In some embodiments, the length L of chamber 102 is 1 cm or more (e.g., 2 cm or more, 3 cm or more, 4 cm or more, 5 cm or more). In certain embodiments, L is 30 cm or less (e.g., 20 cm or less, 15 cm or less, 10 cm or less, 9 cm or less, 8 cm or less, 7 cm or less).

In some embodiments, chamber 102 is spaced from members 104 by a distance s of 0.5 cm or more (e.g., 1 cm or more, 2 cm or more, 3 cm or more, 4 cm or more). In certain embodiments, s is 15 cm or less (e.g., 12 cm or less, 10 cm or less, 8 cm or less, 6 cm or less).

In some embodiments, chamber 102 has a tubular shape that includes a first open end 113 and a second open end 115. In certain embodiments, for example, chamber 102 is cylindrical and has a circular cross-sectional shape, as shown in FIG. 1. More generally, chamber 102 can have a cross-sectional shape that is non-circular, such as a cross-sectional shape that is square, rectangular, hexagonal, or another regular or irregular shape, and can have one or more than one open end.

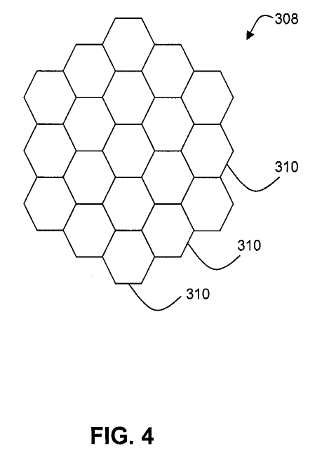

In certain embodiments, the chamber can include a plurality of channels. An embodiment of a multi-channel chamber 308 is shown in FIG. 4. Chamber 308 includes channels 310, each of which has a cross-sectional shape that is hexagonal. The channels 310 are formed, for example, of a material that includes one or more metals such as titanium, tantalum, or both, and joined together by a process such as welding. Chamber 308 has properties that are similar to those described above for chamber 102, and functions similarly in an ion pump system 100.

In some embodiments, ionization of gas atoms 200 can be accomplished by another means in place of, or in addition to, collision of gas atoms 200 with electrons 106. For example, in certain embodiments, ion pump system 100 can include a light source 250, as shown in FIG. 2. Light source 250 can provide photons that are absorbed by gas atoms 200, and which cause photoionization of gas atoms 200 to form ions 202. Photoionization of gas atoms 200 can be a single-photon or a multi-photon process. In general, light provided by light source 250 can include one or more wavelengths from various regions of the electromagnetic spectrum, including ultraviolet light, visible light, and infrared light.

Diffusion of implanted ions 202 out of members 104 is typically facilitated by lattice vibrations of the atoms that form members 104, and by random thermal motions of ions 202. Lattice vibrations can be reduced in amplitude by reducing the temperature of members 104. Thus, in some embodiments, ion pump system 100 can include one or more cooling members in thermal communication with members 104. For example, FIG. 3 shows a cooling member 260 in thermal communication with member 104. Cooling members can, in certain embodiments, include a heat exchanger that is coupled to a cooling system. For example, the heat exchanger can be a Peltier cooler. In some embodiments, the heat exchanger can be a plate-type heat exchanger that is coupled to a liquid nitrogen cooling system, for example.

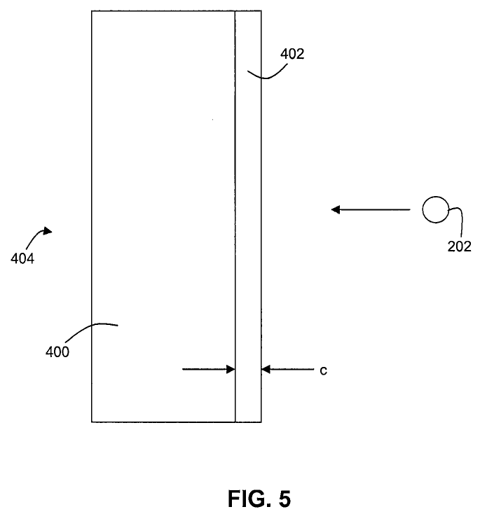

In some embodiments, members 104 can include a substrate and a coating applied to the substrate. FIG. 5 shows a schematic view of a member 404 that includes a substrate 400 and a coating 402 with a thickness c. Substrate 400 typically has properties that are similar to those described above for members 104.

In some embodiments, coating 402 can be formed from a material having an atomic structure with a lattice spacing that is smaller than the average lattice spacing of the material that forms substrate 400. As a result, coating 402 can be penetrated by high energy incident ions 202, which are implanted within substrate 400. However, ions 202 lose some of their kinetic energy due to collisions with atoms in coating 402 and/or substrate 400 and are thermalized in substrate 400. As a result, coating 402 forms an energy barrier that assists in preventing the thermalized, implanted ions 202 from diffusing out of member 404, thereby trapping ions 202 within member 404.

In some embodiments, coating 402 can be formed of a material that includes one or more metals (e.g., a pure metal or an alloy), or a polymer material. For example, coating 402 can be formed of metals such as titanium, tantalum, and aluminum. In certain embodiments, for example, coating 402 can be formed of materials such as polyesters. In some embodiments, coating 402 can be formed of a material such as diamond.

Coating 402 is shown in FIG. 5 as a single layer of material. In general, however, coating 402 can include one or more layers of any of the materials disclosed above. For example, in some embodiments, coating 402 can be formed of a plurality of alternating layers of two or more metals and/or polymer materials.

The thickness c of coating 402 can typically be selected as desired to regulate the magnitude of the energy barrier both to implantation of ions 202 within member 404, and to diffusion of implanted ions 202 out of member 404. In some embodiments, c can be 10 nm or more (e.g., 20 nm or more, 30 nm or more, 50 nm or more, 100 nm or more, 200 nm or more, 500 nm or more) and/or 5 microns or less (e.g., 3 microns or less, 2 microns or less, 1 micron or less).

Substrate 400 can be formed from a variety of materials, including metals, alloys, and polymer materials. For example, in some embodiments, substrate 400 can be formed from a metal such as titanium, tantalum, or both titanium and tantalum. Where substrate 400 includes two or more materials, the two or more materials can be integrally mixed, as in an alloy, or the two or more materials can form a plurality of layers, for example. In general, substrate 400 can be formed from any of the materials disclosed above with respect to members 104.

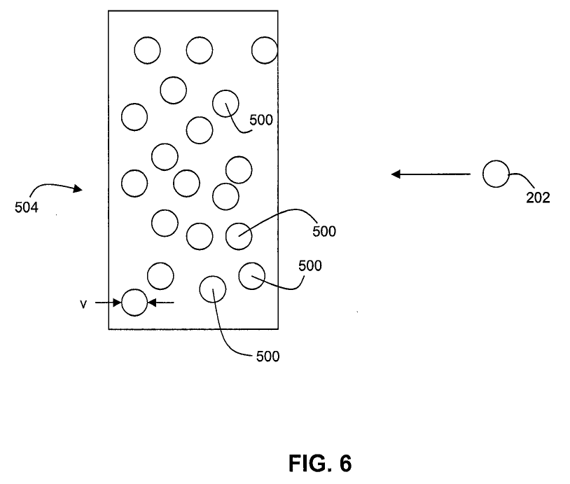

In some embodiments, members 104 can include a plurality of voids, and ions 202 produced in chamber 102 can be collected within the voids. FIG. 6 shows a schematic view of a member 504 that includes a plurality of voids 500 having an average maximum dimension v. Voids 500 are capable of accommodating ions 202. In some embodiments, for example, voids 500 can be macroscopic holes which are evacuated. In certain embodiments, voids 500 can be defect sites within the lattice of member 504 where ions 202 can be energetically trapped. Voids 500 trap ions 202 such that diffusion by ions 202 out of member 504 is energetically unfavorable.

Typically, member 504 is formed from one or more metals such as titanium and/or tantalum. To produce voids 500, for example, the one or more metals can be combined with a sacrificial material to form a solution at high temperature, and then cooled and solidified. Subsequently, the sacrificial material is removed from the solidified mixture by leaching, or by controlled melting (e.g., selective melting of only the sacrificial material) to form voids 500 in the material of member 504. To produce lattice defects in member 504, for example, the material of member 504 can be annealed under suitable conditions.

In some embodiments, the average maximum dimension v of voids 500 can be 1 nm or more (e.g., 2 nm or more, 3 nm or more, 5 nm or more, 10 nm or more, 20 nm or more, 30 nm or more, 50 nm or more) and/or 100 nm or less (e.g., 90 nm or less, 80 nm or less, 70 nm or less, 60 nm or less).

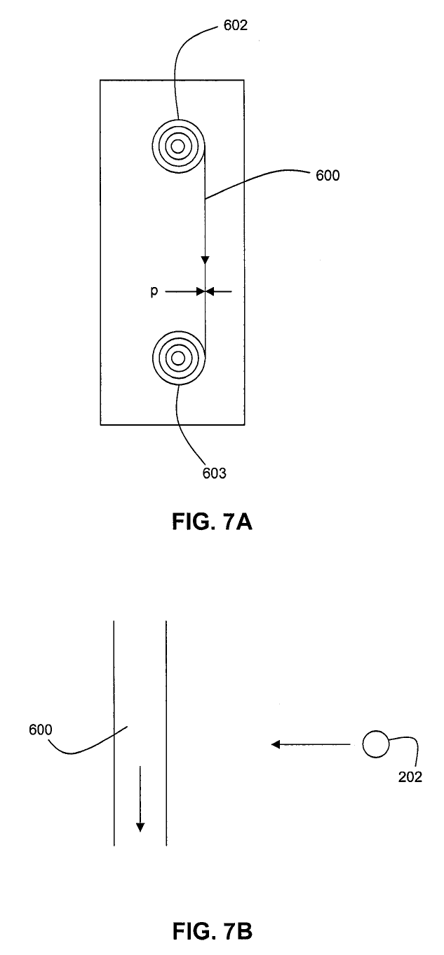

In some embodiments, at least a portion of members 104 can be translated during operation of ion pump system 100. A translating member 600 in the form of a film of thickness p is shown schematically in FIG. 7A. Member 600 is coupled to spools 602 and 603, and is discharged from spool 602 and taken up by spool 603 so that member 600 moves in a spool-to-spool fashion. Ions 202 are incident on translating member 600 as shown in FIG. 7B. Ions 202 that are implanted within member 600 are further buried as successive layers of member 600 are wound around spool 603. As a result, as ion pump system 100 is operated, implanted ions 202 are covered by an increasing number of layers of member 600 wound around spool 603. Thus, diffusion of the implanted ions 202 out of member 600 is hindered and ions 202 remain trapped within member 600 for a longer time that would otherwise occur if member 600 was not wound around spool 603.

The thickness p of member 600 is typically chosen as desired to facilitate winding of member 600 around spools 602 and 603, and to control the sizes of the wound spools. In some embodiments, p is 100 nm more (e.g., 200 nm or more, 300 nm or more, 500 nm or more, 1 micron or more, 5 microns or more, 10 microns or more, 20 microns or more) and/or 500 microns or less (e.g., 300 microns or less, 200 microns or less, 100 microns or less, 50 microns or less).

Member 600 can be formed from any of the materials disclosed above in connection with members 104, 404, and 504, and coating 402. Member 600 can, in general, include a single layer of one or more materials, or member 600 can include a plurality of layers of materials to control the mechanical and chemical properties of member 600, for example.

A total length of member 600 can be selected in conjunction with a translation velocity of member 600 from spool 602 to spool 603 to determine how often member 600 is replaced within ion pump system 100. For example, in some embodiments, the total length of member 600 is 10 m or more (e.g., 20 m or more, 50 m or more, 100 m or more, 500 m or more) and/or 5,000 m or less (e.g., 4,000 m or less, 3,000 m or less, 2,000 m or less, 1,000 m or less).

In some embodiments, the translation velocity of member 600 from spool 602 to spool 603 is 0.1 cm/s or more (e.g., 0.5 cm/s or more, 1 cm/s or more, 1.5 cm/s or more, 2 cm/s or more, 3 cm/s or more) and/or 10 cm/s or less (e.g., 9 cm/s or less, 8 cm/s or less, 7 cm/s or less, 6 cm/s or less, 5 cm/s or less).

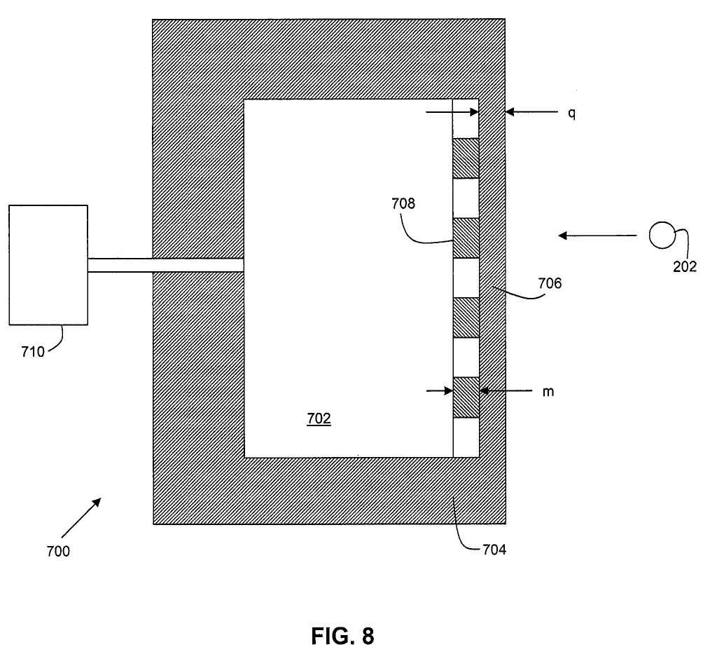

In some embodiments, members 104 include a variable thickness wall that defines a trapped volume within the members. FIG. 8 is a schematic illustration of a member 700 with a variable thickness wall 704. Wall 704 encloses a hollow interior trapped volume 702 that is in fluid communication with a vacuum pump 710. A thin portion of wall 704 is formed by a base layer 706 and a support layer 708 in the form of a grid that provides mechanical support to base layer 706. Base layer 706 has a thickness q that is typically smaller by a factor of 5 or more than a thickness of wall 704 in another region (e.g., near the opening in wall 704 that forms a fluid connection to pump 710). Wall 704, including base layer 706, is typically formed from any of the materials disclosed above in connection with members 104, 404, and 600.

Support layer 708 can be also be formed from any of the materials disclosed above in connection with members 104, 404, and 600. Alternatively, or in addition, support layer 708 can be formed from materials such as aluminum, copper, and steel.

A thickness m of support layer 708 can be chosen to provide adequate mechanical support for base layer 706. For example, in some embodiments, m can be 5 microns or more (e.g., 7 microns or more, 10 microns or more, 15 microns or more) and/or 5 mm or less (e.g., 1 mm or less, 500 microns or less, 100 microns or less).

Trapped volume 702 is pumped by pump 710 which can be, for example, a turbomolecular pump. Ions 202 are incident on base layer 706 from chamber 102 and pass through layer 706 to enter trapped volume 702. Once inside, ions 202 undergo thermalization, and are therefore prevented from diffusing back through layer 706. Instead, ions 202 remain trapped within volume 702 until they are pumped out by pump 710. A steady-state pressure of ions 202 in trapped volume 702 can be maintained so that pump 710 can effectively pump out ions 202 from trapped volume 702, but the rate of diffusion of ions 202 back through base layer 706 is relatively small.

Various embodiments of ion pump systems have been disclosed above. In general, features of the various embodiments can be combined, where possible, to yield other embodiments, to take advantage of the various advantageous properties of each of the embodiments. For example, in general, any of the above embodiments can include photoionization sources, cooling members, members that include a substrate and a coating layer, members that include a plurality of voids, translatable members, and members that include a variable thickness wall that defines a trapped volume.

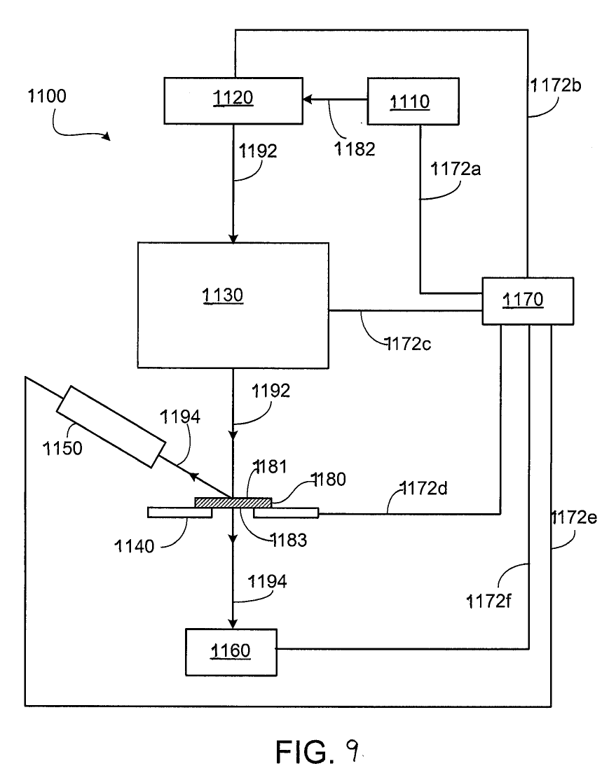

The ion pump systems disclosed above can be used in a variety of vacuum systems. In particular, the ion pump systems can be used in vacuum systems that include a gas field ion source. FIG. 9 shows a schematic diagram of a gas field ion microscope system 1100 that includes a gas source 1110, a gas field ion source 1120, ion optics 1130, a sample manipulator 1140, a front-side detector 1150, a back-side detector 1160, and an electronic control system 1170 (e.g., an electronic processor, such as a computer) electrically connected to various components of system 1100 via communication lines 1172a-1172f. A sample 1180 is positioned in/on sample manipulator 1140 between ion optics 1130 and detectors 1150, 1160. During use, an ion beam 1192 is directed through ion optics 1130 to a surface 1181 of sample 1180, and particles 1194 resulting from the interaction of ion beam 1192 with sample 1180 are measured by detectors 1150 and/or 1160.

In general, it is desirable to reduce the presence of certain undesirable chemical species in system 1100 by evacuating the system. Typically, different components of system 1100 are maintained at different background pressures. For example, gas field ion source 1120 can be maintained at a pressure of approximately 10⁻¹⁰ Torr. When gas is introduced into gas field ion source 1120, the background pressure rises to approximately 10⁻⁵ Torr. Ion optics 1130 are maintained at a background pressure of approximately 10⁻⁸ Torr prior to the introduction of gas into gas field ion source 1120. When gas is introduced, the background pressure in ion optics 1130 typically increases to approximately 10⁻⁷ Torr. Sample 1180 is positioned within a chamber that is typically maintained at a background pressure of approximately 10⁻⁶ Torr. This pressure does not vary significantly due to the presence or absence of gas in gas field ion source 1120.

The pressures of various gases such as helium in gas field ion source 1120 and ion optics 1130 can be controlled via ion pump system 100. In particular, ion pump system 100 can be used to regulate the background pressure of helium gas during operation of the gas field ion microscope system 1100. In general, system 1100 can be any system that includes a gas field ion source, including a gas field ion microscope, a helium ion microscope, a scanning ion microscope, and a scanning helium ion microscope. Gas field ion source 1120 includes, for example, an electrically conductive tip having a terminal shelf with 20 atoms or less, as described in U.S. patent application Ser. No. 11/600,711, filed Nov. 15, 2006, which has been previously incorporated by reference herein.

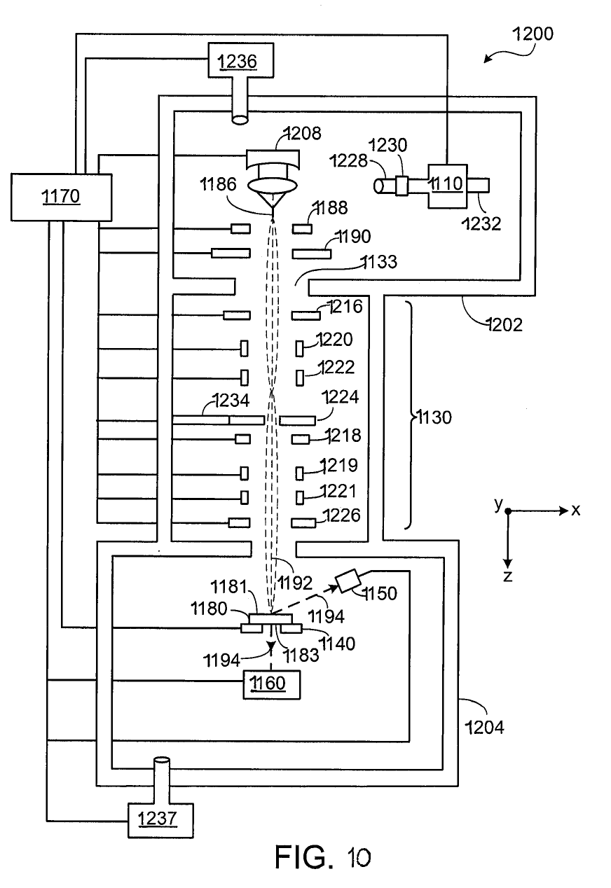

FIG. 10 shows a schematic diagram of a He ion microscope system 1200. Microscope system 1200 includes a first vacuum housing 1202 enclosing a He ion source and ion optics 1130, and a second vacuum housing 1204 enclosing sample 1180 and detectors 1150 and 1160. Gas source 1110 delivers He gas to microscope system 1200 through a delivery tube 1228. A flow regulator 1230 controls the flow rate of He gas through delivery tube 1228, and a temperature controller 1232 controls the temperature of He gas in gas source 1110. The He ion source includes a tip 1186 affixed to a tip manipulator 1208. The He ion source also includes an extractor 1190 and a suppressor 1188 that are configured to direct He ions from tip 1186 into ion optics 1130. Ion optics 1130 include electrodes such as a first lens 1216, alignment deflectors 1220 and 1222, an aperture 1224, an astigmatism corrector 1218, scanning deflectors 1219 and 1221, and a second lens 1226. Aperture 1224 is positioned in an aperture mount 1234. Sample 1180 is mounted in/on a sample manipulator 1140 within second vacuum housing 1204. Detectors 1150 and 1160, also positioned within second vacuum housing 1204, are configured to detect particles 1194 from sample 1180. Gas source 1110, tip manipulator 1208, extractor 1190, suppressor 1188, first lens 1216, alignment deflectors 1220 and 1222, aperture mount 1234, astigmatism corrector 1218, scanning deflectors 1219 and 1221, sample manipulator 1140, and/or detectors 1150 and/or 1160 are typically controlled by electronic control system 1170. Optionally, electronic control system 1170 also controls vacuum pumps 1236 and 1237, which are configured to provide reduced-pressure environments inside vacuum housings 1202 and 1204, and within ion optics 1130.

Vacuum pumps 1236 and 1237 are ion pump systems as disclosed herein. Typically, for example, ion pump systems 1236 and 1237 are in fluid communication with the interior of vacuum housings 1202 and 1204 via one or more conduits, as shown in FIG. 10. In some embodiments, pumps 1236 and/or 1237 can be positioned within housings 1202 and 1204 to facilitate capture of helium gas atoms. Pumps 1236 and 1237, positioned either internal or external to housings 1202 and 1204, can be used to regulate the ambient pressure of helium gas in microscope system 1200.

In some embodiments, system 1200 can also include additional pumps such as, for example, mechanical pumps and/or turbomolecular pumps. The mechanical and/or turbomolecular pumps can assist pumps 1236 and 1237 to achieve a desired helium gas pressure in vacuum housings 1202 and/or 1204. For example, mechanical and/or turbomolecular pumps can be operated to reduce helium gas pressure in housings 1202 and/or 1204 to approximately 10⁻³ Torr or below. Ion pump systems can then be used to realize and/or maintain even lower helium gas pressures in housings 1202 and/or 1204.

Other embodiments are in the claims.

1. A system, comprising:
a chamber; and
a member, at least a portion of the member being capable of translating during use of the system,
wherein the chamber and the member are configured so that during use of the system an electrical potential difference is applied between the chamber and the member so that at least some gas atoms present in the chamber are ionized and at least some of the ions are collected by the member.

2. The system of claim 1, further comprising first and second spools coupled with the member so that, during use, the member moves between the first and second spools in a spool-to-spool fashion.

3. The system of claim 1, wherein the member is in the form of a film.

4. The system of claim 3, wherein a thickness of the film is at least 100 nm or more.

5. The system of claim 3, wherein a thickness of the film is at most 100 microns or less.

6. The system of claim 3, wherein a length of the film is at least 10 m.

7. The system of claim 3, wherein a length of the film is at most 5,000 m.

8. The system of claim 1, wherein the member comprises at least one material selected from the group consisting of a metal, an alloy, and a polymer material.

9. The system of claim 1, wherein the member comprises titanium, tantalum, or both.

10. The system of claim 1, wherein the member comprises a substrate and a coating on the substrate.

11. The system of claim 1, wherein the member includes voids having a maximum dimension of from 10 nm to 100 nm.

12. The system of claim 1, wherein the chamber comprises a hollow interior volume.

13. The system of claim 1, wherein the chamber comprises a first open end and a second open end.

14. The system of claim 13, wherein the member is a first member and the system further comprises a second member, and wherein the first member is positioned at a distance of less than 10 cm from the first open end and the second member is positioned at a distance of less than 10 cm from the second open end.

15. The system of claim 1, further comprising a magnetic field source.

16. The system of claim 1, further comprising a source of electromagnetic radiation.

17. The system of claim 16, wherein the electromagnetic radiation includes at least one type of radiation selected from the group consisting of ultraviolet radiation, visible radiation, and infrared radiation.

18. The system of claim 1, further comprising a voltage source in electrical communication with the chamber and the member, and configured to apply an electrical potential difference between the chamber and the member.

19. The system of claim 1, further comprising a gas source capable of being placed in fluid communication with the chamber.

20. The system of claim 1, further comprising a vacuum chamber in fluid communication with the chamber.

21. The system of claim 20, further comprising a pump in fluid communication with the vacuum chamber.

22. The system of claim 20, further comprising a gas field ion source in the vacuum chamber.

23. The system of claim 22, further comprising ion optics configured to direct an ion beam generated by the gas field ion source toward a surface of a sample, the ion optics comprising electrodes, an aperture, and an extractor.

24. The system of claim 23, further comprising a sample manipulator capable of moving the sample.

25. The system of claim 22, wherein the system is a gas field ion microscope.

26. The system of claim 22, wherein the system is a helium ion microscope.

27. The system of claim 22, wherein the system is a scanning ion microscope.

28. The system of claim 22, wherein the system is a scanning helium ion microscope.

29. The system of claim 22, wherein the gas field ion source comprises an electrically conductive tip having a terminal shelf with 20 atoms or less.

30. A system, comprising:
a chamber; and
a member having voids with an average maximum dimension of from 1 nm to 100 nm,
wherein the chamber and the member are configured so that during use of the system an electrical potential difference is applied between the chamber and the member so that at least some gas atoms present in the chamber are ionized and at least some of the ions are collected within the voids of the member.

31-53. (canceled)

54. A system, comprising:
a chamber; and
a member comprising a substrate and a coating on the substrate,
wherein the chamber and the member are configured so that during use of the system an electrical potential difference is applied between the chamber and the member so that at least some gas atoms present in the chamber are ionized and at least some of the ions are collected within the substrate of the member.

55-81. (canceled)

82. A system, comprising:
a chamber; and
a member having a variable thickness wall that defines a trapped volume within the member,
wherein the chamber and the member are configured so that during use of the system an electrical potential difference is applied between the chamber and the member so that at least some gas atoms present in the chamber are ionized and at least some of the ions are collected within the trapped volume of the member.

83-150. (canceled)
